(19) United States
(12) Patent Application Publication
(10) Pub. No.: US 2024/0198322 A1
(43) Pub. Date: Jun. 20, 2024

(54) VISIBLE LIGHT-SENSITIVE PHOTOCATALYST COMPOSITION AND A VISIBLE LIGHT-SENSITIVE PHOTOCATALYST FILM COMPRISING THE SAME

(71) Applicant: Uniplatek Co., Ltd, Daejeon-si (KR)

(72) Inventors: Suk Hwan KANG, Daejeon-si (KR); Jung Min HEO, Daejeon-si (KR)

(73) Assignee: Uniplatek Co., Ltd, Daejeon-si (KR)

(21) Appl. No.: 18/081,048

(22) Filed: Dec. 14, 2022

(30) Foreign Application Priority Data
Dec. 14, 2022 (KR) 10-2022-0174958

(51) Int. Cl. B01J 35/00; B01J 21/06; B01J 23/745; B01J 23/89; B01J 37/02; C23C 14/08; C23C 14/14; C23C 14/34

(52) U.S. Cl. CPC B01J 35/004; B01J 21/063; B01J 23/745; B01J 23/894; B01J 23/8993; B01J 37/0215; C23C 14/08; C23C 14/14; C23C 14/3407; B01J 2523/18; B01J 2523/3712; B01J 2523/47; B01J 2523/69; B01J 2523/842

(57) ABSTRACT

The present invention relates to a visible light-sensitive photocatalyst composition and a visible light-sensitive photocatalyst film comprising the same, and more particularly, to a visible light-sensitive photocatalyst composition and a visible light-sensitive photocatalyst film comprising the same, which has catalytic properties of oxidizing and decomposing organic matter in the air in not only ultraviolet rays but also visible rays, sunlight and indoor lights, and is capable of removing harmful substances, deodorizing, sterilizing, etc., and can provide visibility.

### TECHNICAL FIELD

The present invention relates to a visible light-sensitive photocatalyst composition and a visible light-sensitive photocatalyst film comprising the same, and more particularly, to a visible light-sensitive photocatalyst composition and a visible light-sensitive photocatalyst film comprising the same, which has catalytic properties of oxidizing and decomposing organic matter in the air in not only ultraviolet rays but also visible rays, sunlight and indoor lights, and is capable of removing harmful substances, deodorizing, sterilizing, etc., and can provide visibility.

### BACKGROUND ART

Recently, as the importance of health and the environment has been highlighted due to the corona, attention has been focused on the state of air in indoor and outdoor spaces.

Indoor air is polluted by volatile organic compounds generated from building materials or harmful gases generated during cooking, fine dust, and the like, and circulating the contaminated air threatens human health.

Photocatalysts are mainly used to purify indoor air. Ultraviolet rays are irradiated on the surface of the photocatalyst to generate radical hydroxyl ions and radical peroxide ions, and their strong oxidizing power decomposes harmful substances adsorbed on the surface of the photocatalyst to purify indoor air.

However, since the photocatalyst reacts only under limited conditions in the presence of ultraviolet rays, it cannot effectively purify indoor air because it does not react in an environment where visible rays such as LEDs and fluorescent lights are generated indoors.

Therefore, it is necessary to develop technology that has catalytic properties to oxidize and decompose organic matter in the air in visible light, sunlight, and indoor light as well as ultraviolet rays, and can remove harmful substances, deodorize, and sterilize.

### PRIOR ART DOCUMENT

(Patent Document 1) Korean Patent Registration No. 10-0609393
(Patent Document 2) Korean Patent Registration No. 10-0395264

### DISCLOSURE

### Technical Problem

The present invention is to solve the problems of the prior art, and an object of the present invention is to provide a visible light-sensitive photocatalyst composition and a visible light-sensitive photocatalyst film, which has a catalytic property of oxidizing and decomposing organic matter in the air not only in ultraviolet rays but also in visible rays, sunlight and indoor lights, and removes harmful substances, deodorizes, and sterilizes, and is capable of imparting visibility.

### Technical Solution

In order to achieve the above object, the present invention provides a method for manufacturing a visible light-sensitive photocatalyst film comprising:
(a) preparing a visible light-sensitive photocatalyst composition including titanium dioxide, tungsten trioxide, and a cocatalyst;
(b) preparing a substrate; and
(c) forming a film on the substrate through sputtering using the visible light-sensitive photocatalyst composition as a sputtering target.

In one embodiment of the present invention, the photocatalyst composition in step (a) is characterized by including 40 to 80 parts by weight of tungsten trioxide and 1 to 10 parts by weight of a cocatalyst based on 100 parts by weight of titanium dioxide.

In one embodiment of the present invention, the cocatalyst in step (a) is characterized in that at least one of silver, tin, copper, gold, platinum, tungsten, zinc sulfide, cerium dioxide and iron oxide is used.

In one embodiment of the present invention, the cocatalyst in step (a) is characterized in that silver, cerium dioxide and iron oxide are used.

In addition, the present invention provides a visible light-sensitive photocatalyst film prepared by the above manufacturing method.

### Advantageous Effect

The present invention can provide a visible light-sensitive photocatalyst composition and a visible light-sensitive photocatalyst film, which has a catalytic property of oxidizing and decomposing organic matter in the air in visible light, sunlight and indoor light as well as ultraviolet light, and can remove harmful substances, deodorize, and sterilize, and provide visibility.

### MODE FOR THE INVENTION

The present invention will be described in detail based on the following examples. The terms, examples, etc. used in the present invention are merely exemplified to explain the present invention in more detail and help the understanding of those skilled in the art, and the scope of the present invention should not be construed as being limited thereto.

Technical terms and scientific terms used in the present invention represent meanings commonly understood by those of ordinary skill in the art to which this invention belongs, unless otherwise defined.

The present invention relates to a method for manufacturing a visible light-sensitive photocatalyst film comprising;
(a) preparing a visible light-sensitive photocatalyst composition comprising titanium dioxide, tungsten trioxide and a cocatalyst;
(b) preparing a substrate; and
(c) forming a film on the substrate through sputtering using the visible light-sensitive photocatalyst composition as a sputtering target;

The step (a) may prepare a visible light-sensitive photocatalyst composition including titanium dioxide (TiO₂), tungsten trioxide (WO₃) and a cocatalyst.

Preferably, anatase titanium dioxide is used as the titanium dioxide.

The visible light-sensitive photocatalyst composition may be prepared by mixing titanium dioxide, tungsten trioxide, and a cocatalyst and then firing them.

By using a mixture of titanium dioxide, tungsten trioxide, and a cocatalyst, some of the electrons excited from tungsten trioxide move to titanium dioxide, and some of the excited holes move to tungsten trioxide, so excited electrons and holes are effectively separated, thereby lowering the probability of their recombination, thereby increasing the photocatalytic effect in visible light.

The photocatalyst composition may include 40 to 80 parts by weight of tungsten trioxide and 1 to 10 parts by weight of a cocatalyst based on 100 parts by weight of titanium dioxide.

When the content satisfies the above numerical range, photocatalytic efficiency, deodorization rate, sterilization, etc. can be maximized.

In addition, one or more of silver, tin, copper, gold, platinum, tungsten, zinc sulfide, cerium dioxide, and iron oxide (Fe₂O₃) may be used as the cocatalyst.

In the present invention, silver, cerium dioxide, and iron oxide may be mixed and used as the cocatalyst.

At this time, the weight ratio of silver, cerium dioxide, and iron oxide is preferably 100:30 to 60:10 to 30, and when the weight ratio satisfies the above numerical range, photocatalytic efficiency, deodorization rate, sterilization, and the like can be maximized.

In addition, in the present invention, silver, tin, cerium dioxide, and iron oxide may be mixed and used as the cocatalyst.

At this time, the weight ratio of silver, tin, cerium dioxide, and iron oxide is preferably 100:5 to 20:30 to 60:10 to 30, and when the weight ratio satisfies the above numerical range, photocatalytic efficiency, deodorization rate, sterilization, etc. are can be maximized.

In addition, in the present invention, silver, tin, tungsten, cerium dioxide, and iron oxide may be mixed and used as the cocatalyst.

At this time, the weight ratio of silver, tin, tungsten, cerium dioxide and iron oxide is preferably 100:5 to 20:1 to 10:30 to 60:10 to 30, and when the weight ratio satisfies the above numerical range, the photocatalytic efficiency and deodorization rate, sterilization, etc. can be maximized.

The step (b) is a step of preparing a substrate, and glass, metal, ceramic, wood, plastic, fiber, fabric, concrete, etc. may be used as the substrate.

In the step (c), a film may be formed on the substrate through sputtering using the visible light-sensitive photocatalyst composition as a sputtering target.

For the sputtering process, after putting the substrate and the sputtering target into the sputtering device, injecting gas such as argon under vacuum, and when the ions formed by the applied power collide with the sputtering target, the particles forming the sputtering target are detached from the sputtering target and are coated on the surface of the substrate.

The visible light-sensitive photocatalyst composition may be used as a sputtering target and coated to a uniform thickness on a surface of a substrate.

The photocatalyst film formed on the surface of the substrate can adsorb, remove, deodorize, and sterilize viruses, microorganisms, fine dust, harmful gases, and harmful substances.

In addition, in the present invention, after the step (c), the photocatalyst film may be surface treated with a silane coupling agent oligomer prepared by reaction of an acrylate group-containing silane coupling agent, an epoxy group-containing silane coupling agent, 2-hydroxyethyl acrylate (HEA) and 2-hydroxyethyl methacrylate (HEMA).

The oligomer may be bonded to the surface of the photocatalyst film to introduce a plurality of hydroxyl groups and ester groups into the photocatalyst film.

A plurality of functional groups included in the oligomer can improve photocatalytic efficiency by allowing viruses, microorganisms, fine dust, harmful gases, and harmful substances to be easily adsorbed.

The acrylate group-containing silane coupling agent includes 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, methacryloxymethyltriethoxysilane, methacryloxymethyltrimethoxysilane and the like.

The epoxy group-containing silane coupling agent includes 2-glycidoxyethylmethyldimethoxysilane, 2-glycidoxyethylmethyldiethoxysilane, 3-glycidoxypropylmethyldimethoxysilane, 3-glycidoxypropylmethyldiethoxysilane, 2-glycidoxyethyltrimethoxysilane, 2-glycidoxyethyltriethoxysilane, 3-glycidoxypropyltrimethoxysilane, 3-glycidoxypropyltriethoxysilane, 2-(3,4-epoxycyclohexyl)ethylmethyldimethoxysilane, 2-(3,4-epoxycyclohexyl)ethylmethyldiethoxysilane, 3-(3,4-epoxycyclohexyl)propylmethyldimethoxysilane, 3-(3,4-epoxycyclohexyl)propylmethyldiethoxysilane, 2-(3,4-epoxycyclohexyl)ethyltrimethoxysilane, 2-(3,4-epoxycyclohexyl)ethyltriethoxysilane, 3-(3,4-epoxycyclohexyl)propyltrimethoxysilane, 3-(3,4-epoxycyclohexyl)propyltriethoxysilane, and the like.

The weight ratio of the acrylate group-containing silane coupling agent, the epoxy group-containing silane coupling agent, 2-hydroxyethyl acrylate (HEA) and 2-hydroxyethyl methacrylate (HEMA) is preferably 10 to 40:100:20 to 50:10 to 30, and when the weight ratio satisfies the above numerical range, photocatalytic efficiency, deodorization rate, antibacterial properties, etc. can be maximized.

The oligomer preferably has a weight average molecular weight of 5,000 to 50,000 g/mol.

The oligomer is preferably used in an amount of 1 to 10 parts by weight based on 100 parts by weight of the photocatalyst film.

In addition, the present invention relates to a method for manufacturing a visible light-sensitive photocatalyst film comprising;
(a) preparing a photocatalyst composition containing titanium dioxide and tungsten trioxide;
(b) preparing a cocatalyst composition comprising a cocatalyst;
(c) preparing a substrate; and
(d) forming a film on the substrate through sputtering using the photocatalyst composition as a first sputtering target and the cocatalyst composition as a second sputtering target.

For the sputtering process, after putting the substrate and the sputtering target into the sputtering device, injecting gas such as argon under vacuum, and when the ions formed by the applied power collide with the sputtering target, the particles forming the sputtering target are detached from the sputtering target and can be coated on the surface of the substrate.

The photocatalyst composition is used as a first sputtering target, and the cocatalyst composition is used as a second sputtering target, so that the surface of a substrate can be coated by titanium dioxide, tungsten trioxide, and a cocatalyst in a uniform thickness through a sputtering process while titanium dioxide, tungsten trioxide, and a cocatalyst are mixed.

At this time, the contents of titanium dioxide, tungsten trioxide, and cocatalyst included in the photocatalyst film may be adjusted by adjusting the sputtered contents of the first sputtering target and the second sputtering target.

The photocatalyst film may include 40 to 80 parts by weight of tungsten trioxide and 1 to 10 parts by weight of a cocatalyst based on 100 parts by weight of titanium dioxide.

The photocatalytic film formed on the surface of the substrate can adsorb, remove, deodorize, and sterilize viruses, microorganisms, fine dust, harmful gases, and harmful substances.

In addition, the present invention relates to a visible light-sensitive photocatalyst film prepared by the above manufacturing method.

The visible light-sensitive photocatalyst film of the present invention has a catalytic property of oxidizing and decomposing organic matter in the air under visible light, sunlight, and indoor light as well as ultraviolet rays, and can remove harmful substances, deodorize, sterilize, etc., and improve visibility.

The present invention will be described in detail through Examples and Comparative Examples below. The following examples are only exemplified for the practice of the present invention, and the content of the present invention is not limited by the following examples.

### Example 1

100 parts by weight of titanium dioxide, 60 parts by weight of tungsten trioxide (WO₃), and 5 parts by weight of silver powder were added to distilled water, mixed, dried at 110° C. for 2 hours, and then calcined at 500° C. for 5 hours to prepare a visible light-sensitive photocatalyst composition.

After the PET substrate and the sputtering target were put into the sputtering device, argon was injected under vacuum and sputtering was performed for 10 minutes.

At this time, the visible light-sensitive photocatalyst composition was used as a sputtering target.

A photocatalyst film coated on the PET substrate was prepared.

### Example 2

A photocatalyst film was prepared in the same manner as in Example 1, except that 30 parts by weight of tungsten trioxide was used.

### Example 3

A photocatalyst film was prepared in the same manner as in Example 1, except that 90 parts by weight of tungsten trioxide was used.

### Example 4

A photocatalyst film was prepared in the same manner as in Example 1, except that 5 parts by weight of a mixed powder of silver, cerium dioxide, and iron oxide was used instead of 5 parts by weight of silver powder.

At this time, the weight ratio of silver, cerium dioxide and iron oxide was adjusted to 100:40:20.

### Example 5

100 parts by weight of titanium dioxide and 60 parts by weight of tungsten trioxide were added to distilled water, mixed, dried at 110° C. for 2 hours, and then calcined at 500° C. for 5 hours to prepare a photocatalyst composition.

100 parts by weight of silver, 40 parts by weight of cerium dioxide, and 20 parts by weight of iron oxide were added to distilled water, mixed, dried at 110° C. for 2 hours, and then calcined at 500° C. for 5 hours to prepare a cocatalyst composition.

After the PET substrate and the sputtering target were put into the sputtering device, argon was injected under vacuum and sputtering was performed for 10 minutes.

At this time, the photocatalyst composition was used as a first sputtering target and the cocatalyst composition was used as a second sputtering target.

A photocatalyst film coated on the PET substrate was prepared.

The contents of titanium dioxide, tungsten trioxide, and cocatalyst included in the photocatalyst film were adjusted by adjusting the sputtered contents of the first sputtering target and the second sputtering target, and the photocatalyst film contained 100 parts by weight of titanium dioxide and tungsten trioxide 60 parts by weight and 5 parts by weight of a cocatalyst.

### Example 6

Silane coupling agent oligomers were prepared by reacting 3-methacryloxypropyltrimethoxysilane, 3-glycidoxypropyltrimethoxysilane, 2-hydroxyethyl acrylate (HEA) and 2-hydroxyethyl methacrylate (HEMA)

Here, the weight ratio of 3-methacryloxypropyltrimethoxysilane, 3-glycidoxypropyltrimethoxysilane, 2-hydroxyethyl acrylate (HEA) and 2-hydroxyethyl methacrylate (HEMA) is 30:100:30:20.

The photocatalyst film prepared in Example 1 was surface treated with the oligomer. At this time, 5 parts by weight of the oligomer was used based on 100 parts by weight of the photocatalyst film.

### Comparative Example 1

100 parts by weight of titanium dioxide, 60 parts by weight of tungsten trioxide, and 5 parts by weight of silver powder were added to distilled water, mixed, dried at 110° C. for 2 hours, and then calcined at 500° C. for 5 hours to prepare a visible light-sensitive photocatalyst composition.

The photocatalyst composition was dispersed in distilled water, applied to a PET substrate, and then dried to prepare a photocatalyst film coated on the PET substrate.

Deodorization and antibacterial properties of the photocatalyst films prepared in Examples and Comparative Examples were measured, and the results are shown in Table 1 below.

### (Deodorizing)

The prepared photocatalyst film was placed under fluorescent light, and then the deodorization performance was measured.

Trimethylamine and formaldehyde removal rates were measured using a detector tube according to KS I 2218:2009 standard.

### (Antibacterial)

The sterilization performance of the prepared photocatalyst film was measured.

E. coli (Escherichia coli ATCC 25922) and Salmonella (Salmonella typhimurium IFO 14193) removal rates were measured after culturing for 10 seconds according to the KCL-FIR-1002:2011 standard.

TABLE 1

| | | Example | | | | | | Comparative |
|---|---|---|---|---|---|---|---|---|
| | | 1 | 2 | 3 | 4 | 5 | 6 | Example 1 |
| deodorizing | Trimethylamine | 91 | 82 | 84 | 97 | 96 | 98 | 68 |
| (%) | formaldehyde | 93 | 84 | 83 | 99 | 99 | 99 | 71 |
| antibacterial | E. coli | 95 | 88 | 89 | 99 | 99 | 99 | 62 |
| (%) | Salmonella | 92 | 87 | 86 | 99 | 99 | 99 | 65 |

From the results of Table 1, it can be seen that the photocatalyst films of Examples 1 to 6 have excellent deodorizing and antibacterial properties. In particular, Examples 1 and 4 to 6 have the most excellent properties.

On the other hand, it can be seen that Comparative Example 1 has inferior properties compared to Examples.

1. A method for manufacturing a visible light-sensitive photocatalyst film comprising:
(a) preparing a visible light-sensitive photocatalyst composition including titanium dioxide, tungsten trioxide, and a cocatalyst;
(b) preparing a substrate; and
(c) forming a film on the substrate through sputtering using the visible light-sensitive photocatalyst composition as a sputtering target.

2. A method according to claim 1,
wherein the photocatalyst composition in step (a) comprises 40 to 80 parts by weight of tungsten trioxide and 1 to 10 parts by weight of a cocatalyst based on 100 parts by weight of titanium dioxide.

3. A method according to claim 2,
wherein at least one of silver, tin, copper, gold, platinum, tungsten, zinc sulfide, cerium dioxide and iron oxide is used as the cocatalyst in step (a).

4. A method according to claim 3,
wherein the cocatalyst in step (a) is a mixture of silver, cerium dioxide and iron oxide.

5. A visible light-sensitive photocatalyst film prepared by the method of claim 1.
